(19) United States
(12) Patent Application Publication
(10) Pub. No.: US 2009/0258469 A1
(43) Pub. Date: Oct. 15, 2009

(54) METHOD OF MANUFACTURING SEMICONDUCTOR DEVICE

(75) Inventor: Yasuhiko UEDA, Tokyo (JP)

Correspondence Address: YOUNG & THOMPSON, 209 Madison Street, Suite 500, ALEXANDRIA, VA, 22314, US

(73) Assignee: ELPIDA MEMORY, INC., Tokyo (JP)

(21) Appl. No.: 12/423,238

(22) Filed: Apr. 14, 2009

(30) Foreign Application Priority Data
Apr. 15, 2008 (JP) 2008-105690

(51) Int. Cl. H01L 21/02

(52) U.S. Cl. 438/386; 257/E21.008

(57) ABSTRACT

In a method of manufacturing a semiconductor device, a carbon-containing film having electrical conductivity is formed so as to cover a first insulating film, a discharge plug and a conductor plug. A first conductive film is formed so as to pass through the carbon-containing film and to be in contact with the conductor plug. The first conductive film is exposed by removing the carbon-containing film.

This application is based upon and claims the benefit of priority from Japanese Patent Application No. 2008-105690, filed on Apr. 15, 2008, the disclosure of which is incorporated herein in its entirety by reference.

### BACKGROUND OF THE INVENTION

1. Field of the Invention

The present invention relates to a method of manufacturing a semiconductor device such as a capacitor.

2. Description of the Related Art

As the capacity of semiconductor devices has been increased in recent years, the area allowed for capacitors as one of principal components of the semiconductor devices has necessarily been reduced. Thus, in the field of the semiconductor devices, there are demands for capacitors capable of providing a high capacity with a smaller occupancy area. In order to manufacture such capacitors, it is necessary to form a cylinder hole (also referred to as a deep bore) having a high aspect ratio in a vertical direction relative to a thick interlayer film formed on the principal surface of a semiconductor substrate.

After a lower electrode is formed on the surface of the cylinder hole, a so-called “trimming process” must be performed to remove the thick interlayer film by means of wet etching using a chemical solution such as hydrofluoric acid. This wet etching may induce a problem of collapse of the lower electrode.

In order to solve this problem, Japanese Laid-Open Patent Publication No. 2006-135261 (Patent Document 1) describes a method of using an amorphous carbon film as a sacrificial interlayer film. According to this method, a deep bore is formed by plasma-etching the amorphous carbon, a lower electrode is formed on the inner wall of the deep bore, and then the amorphous carbon is removed. The technique disclosed in Patent Document 1 takes note of the fact that amorphous carbon can be removed using only oxygen and therefore other components not to be removed are not affected significantly by the removal process. Thus, the collapse of the lower electrode is prevented by employing the trimming process for removing the amorphous carbon with the use of oxygen.

In this respect, a semiconductor device, particularly a DRAM (Dynamic Random Access Memory) device has a capacitor composed of a lower electrode formed on the surface of the inner wall of a cylinder hole, a capacitive insulating film formed on the surface of the lower electrode, and an upper electrode formed in the inside of the lower electrode with the capacitive insulating film interposed therebetween. In order to address further refinement of semiconductor devices in the future, this type of capacitors are required to increase the surface area of electrodes and to increase the capacity by increasing the depth of the cylinder hole, in other words, by improving the aspect ratio.

However, the aspect ratio achievable by presently available manufacturing methods is limited to about 15 to 20. This is because as the depth of a cylinder hole is increased, the extent of side etching occurring during the formation of the cylinder hole becomes more serious, resulting in a phenomenon called bowing, in which the side wall of the cylinder hole bulges outward.

The bowing is caused, for example, by the fact that when cations pass through the opening of a mask pattern during dry etching, the cation orbits are curved by the electrical attracting force exerted by the electric charge of the mask pattern. In other words, the charge-up during dry etching is believed to be a main cause of the bowing. For this reason, even if an attempt is made to form a cylinder hole having an aspect ratio of 20 or more, local side etching will occur in the vicinity of the mouth of the cylinder hall resulting in a short circuit between adjacent capacitors.

According to the technique described in Patent Document 1, amorphous carbon is electrically floating. Therefore, the charge-up during plasma etching cannot be avoided and hence it is difficult to prevent the bowing.

Japanese Laid-Open Patent Publication No. 2006-319058 (Patent Document 2) describes a method for avoiding the charge-up in an insulating film during formation of a deep bore. According to this technique, a flow-through electrode (discharge plug) to be connected to a semiconductor substrate is provided in an insulating film formed of a silicon oxide film before forming a deep bore in the insulating film by plasma etching, and a hard mask used for the formation of the deep bore is made of a conductor.

### SUMMARY

In the technique described in Patent Document 2, the bowing is prevented by providing a discharge path to discharge the electric charge during the plasma etching, specifically a path formed by the hard mask made of a conductor and the flow-through electrode. However, since the interlayer film is an insulating film formed of a silicon oxide film, the path for the charge to reach the flow-through electrode is provided only by the electrically conductive hard mask. As a result, the discharge path becomes so long that the charge-up cannot be prevented effectively.

The present invention seeks to solve one or more of the above problems, or to improve upon those problems at least in part.

In one embodiment, in a method of manufacturing a semiconductor device, a carbon-containing film having electrical conductivity is formed so as to cover a first insulating film, a discharge plug and a conductor plug. A first conductive film is formed so as to pass through the carbon-containing film and to be in contact with the conductor plug. The first conductive film is exposed by removing the carbon-containing film.

### BRIEF DESCRIPTION OF THE DRAWINGS

The above features and advantages of the present invention will be more apparent from the following description of certain preferred embodiments taken in conjunction with the accompanying drawings, in which

FIG. 1 is a cross-sectional view showing a semiconductor device according to an exemplary embodiment of the present invention;

FIGS. 2A and 2B are cross-sectional views sequentially showing manufacturing steps of the semiconductor device shown in FIG. 1;

FIGS. 3A and 3B are cross-sectional views sequentially showing manufacturing steps following those shown in FIGS. 2A and 2B;

FIGS. 4A and 4B are cross-sectional views sequentially showing manufacturing steps following those shown in FIGS. 3A and 3B;

FIGS. 5A and 5B are cross-sectional views sequentially showing manufacturing steps following those shown in FIGS. 4A and 4B;

FIGS. 6A and 6B are cross-sectional views sequentially showing manufacturing steps following those shown in FIGS. 5A and 5B;

FIGS. 7A and 7B are cross-sectional views sequentially showing manufacturing steps following those shown in FIGS. 6A and 6B; and

FIG. 8 is a cross-sectional view showing a manufacturing step following those shown in FIGS. 7A and 7B.

### DETAILED DESCRIPTION OF EXEMPLARY EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

An exemplary embodiment of the present invention will be described in detail with reference to the attached drawings.

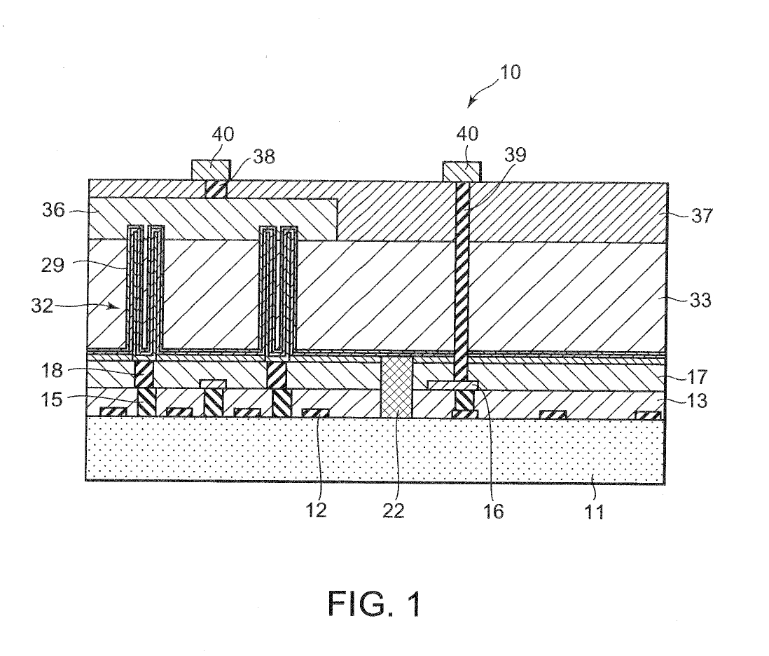

FIG. 1 is a cross-sectional view showing a semiconductor device according to an exemplary embodiment of the present invention. The semiconductor device 10 is a DRAM device, having a diffusion layer (not shown) formed in a region of the surface of a semiconductor substrate 11, interlayer insulating films 13 and 17 formed on top of the diffusion layer, conductor plugs 15 and 18 passing respectively through the interlayer insulating films 13 and 17 to be in contact with the surface of the diffusion layer, and a discharge plug 22 in contact with a region of the surface of the semiconductor substrate 11 not including the diffusion layer. First wiring lines (word lines) 12 are formed on the surface of the semiconductor substrate 11, and second wiring lines (bit lines) 16 are formed on the interlayer insulating film 13. The conductor plugs 18 are formed to be in contact with the conductor plugs 15.

The semiconductor device 10 further has capacitors 32 in contact with the conductor plugs 18, an interlayer insulating film (backfill interlayer film) 33 deposited so as to expose the top parts of the capacitors 32, a plate electrode 36 in contact with the top parts of the capacitors 32, an interlayer insulating film 37 covering the plate electrode 36 and the backfill interlayer film 33, contacts 38 and 39, and wiring lines 40 in contact with the contacts 38 and 39, respectively.

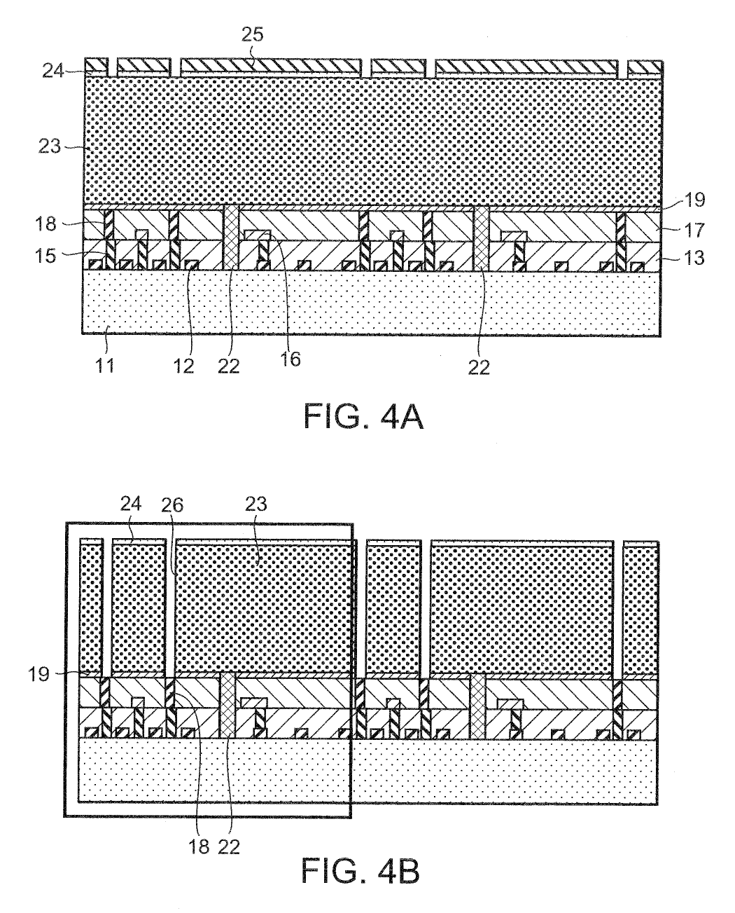

Each of the capacitors 32 has a crown shape formed by trimming a cylinder holes (see FIG. 4B). The cylinder hole has a high aspect ratio, and has a side wall with a vertical profile. This means that the capacitors 32 can be formed without causing collapse of lower electrodes 29 even if the cylinder holes are trimmed during the fabrication thereof, and are allowed to have a large capacity with a small occupancy area. Such capacitors are applicable to those DRAM devices whose configurations are further refined.

Each cylinder hole is formed by ensuring a discharge path for discharging the electric charge to prevent the charge-up during etching and to prevent the so-called bowing effectively. The discharge path is formed of the discharge plug 22, and an amorphous carbon film having electrical conductivity formed in contact with the discharge plug 22 before deposition of the backfill interlayer film 33 (see FIG. 4A).

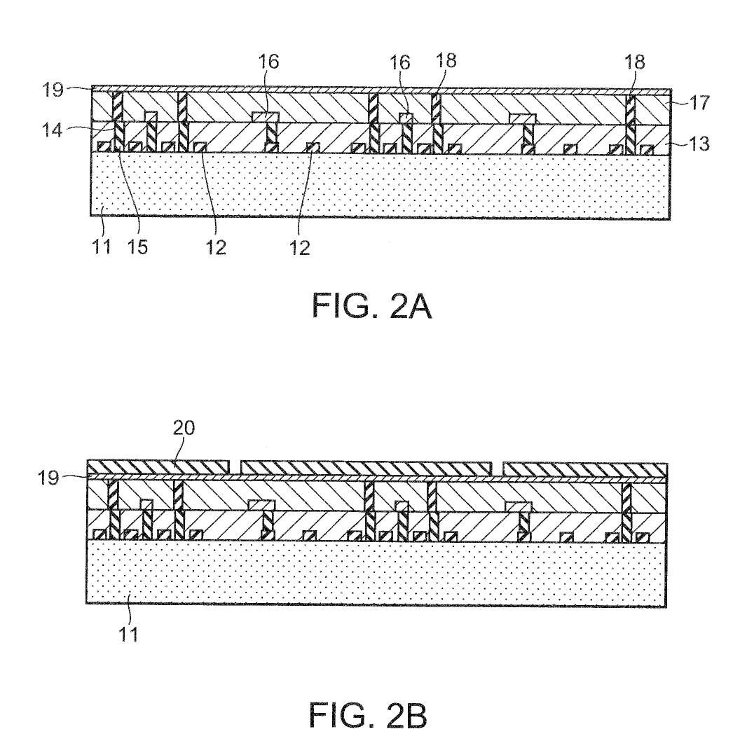

Referring to FIGS. 2 to 8, the steps for manufacturing the semiconductor device 10 of FIG. 1 will be described in detail. First, in the process shown in FIG. 2A, a well (not shown) and an element isolation oxide film (not shown) are formed in a region of the surface of the semiconductor substrate 11. Next, first wiring lines 12 for providing word lines or the like are formed on the semiconductor substrate 11 by a known method. An impurity is injected with the word lines used as an injection mask, so that a diffusion layer (not shown) is formed in a region of the surface of the semiconductor substrate 11 in a self-aligning manner.

Then, a first interlayer insulating film 13 is formed on the semiconductor substrate 11 to cover the first wiring lines 12, and the surface thereof is flattened by the CMP (Chemical Mechanical Polish) method. Subsequently, contact holes 14 are formed to pass through the first interlayer insulating film 13 to reach the surface of the diffusion layer in the semiconductor substrate 11, and then the contact holes 14 are filled with a conductor material to form first conductor plugs 15. Second wiring lines 16 for providing bit lines or the like are then formed on the first interlayer insulating film 13 to be connected to the first conductor plugs 15.

Subsequently, a second interlayer insulating film 17 is formed on the first interlayer insulating film 13 to cover the second wiring lines 16, and the surface thereof is flattened by the CMP method. Further, holes are opened to pass through the second interlayer insulating film 17 and to reach the first conductor plugs 15, and then the holes are filled with a conductor material to form second conductor plugs 18. Then, a plug protecting film 19 made of silicon nitride is formed to cover the second interlayer insulating film 17 and the second conductor plugs 18, in order to protect the top surface of the second conductor plugs 18.

Subsequently, in the process shown in FIG. 2B, the plug protecting film 19 is covered with a photoresist (PR) 20 which is patterned such that parts of the photoresist corresponding to the surface regions of the semiconductor substrate 11 not including the diffusion layer therein are opened. The diffusion layer in the semiconductor substrate 11 forms a source or drain electrode of a cell transistor. The discharge plug 22 is formed, for example, to be connected to a region of the surface of a peripheral circuit not having the diffusion layer formed therein.

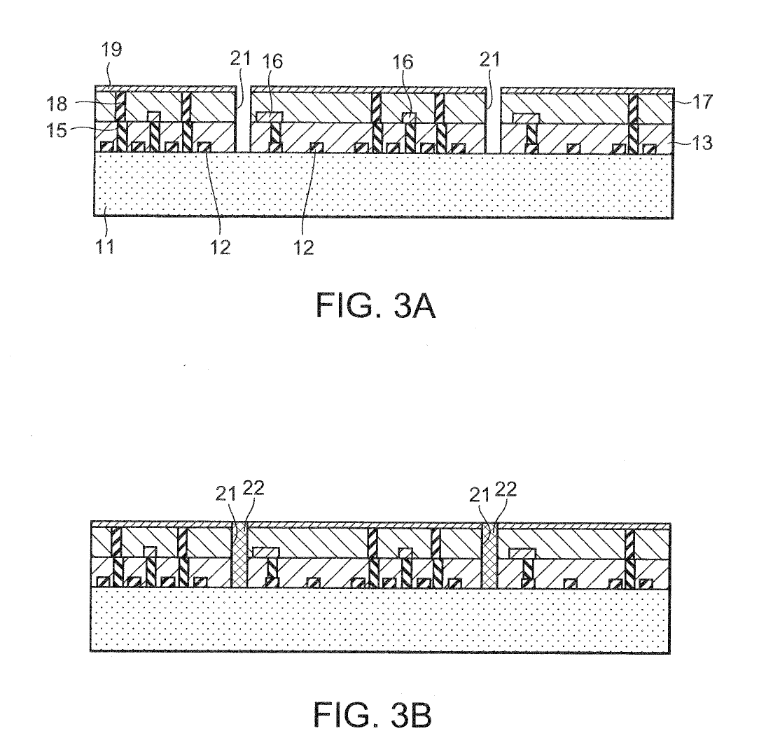

Next, in the process shown in FIG. 3A, through-holes 21 are formed by dry etching the oxide film, using the photoresist 20 as a mask. After that, the photoresist 20 is removed by ashing (O₂ plasma processing). As shown in FIG. 3A, the through-holes 21 pass through the plug protecting film 19, the second interlayer insulating film 17 and the first interlayer insulating film 13 to be in contact with the region of the surface of the semiconductor substrate 11 not having the diffusion layer therein. The dry etching of the oxide film is performed by using a commercially available parallel-plate-type RF plasma etching apparatus. The gas conditions are set such that C₄F₈/Ar/O₂=25/400/22 (sccm), and the pressure is 40 mTorr. The size of the through-holes 21 is set such that the diameter is 250 nm, and the height is 800 nm.

Subsequently, in the process shown in FIG. 3B, the through-holes 21 are filled with TiN and W by using a CVD (chemical vapor deposition) apparatus to form flow-through electrodes (discharge plugs) 22. The TiN is deposited to form a film with a thickness of 30 nm, and the W is deposited to form a film with a thickness of 300 nm, and then excessive W on the surface is removed by the CMP. The discharge plugs 22 form a part of the discharge path for discharging the electric charge to the surface of the region of the semiconductor substrate 11 not having the diffusion layer therein when dry etching the cylinder holes in a later process.

Next, in the process shown in FIG. 4A, a film principally composed of carbon, for example, an amorphous carbon (a-C) film 23 is formed as a sacrificial interlayer film to a thickness of 2400 nm. The amorphous carbon film 23 is in contact with the discharge plugs 22, and forms a discharge path together with the discharge plugs 22.

Further, a hard mask (SiO₂) 24 is formed by CVD to a thickness of 80 nm in order to process the amorphous carbon 23. The hard mask 24 is then covered with a photoresist 25 patterned to have 80 nm diameter holes, and the hard mask 24 is etched.

Subsequently, in the process shown in FIG. 4B, the amorphous carbon 23 is dry-etched, using principally the hard mask (SiO₂) 24 as a mask, to form cylinder holes 26. As shown in FIG. 4B, the cylinder holes 26 pass through the amorphous carbon 23 and the plug protecting film 19 to be in contact with the second conductor plugs 18. The cylinder holes 26 have a side wall with a vertical profile and no bowing is observed there. A detailed description will be made of principles for preventing the bowing during the dry etching of the cylinder holes 26.

Firstly, the etching is conducted by using a commercially available RF2 frequency parallel-plate-type plasma etching apparatus. The gas conditions are set such that NH₃/Ar/O₂=300/200/30 (sccm) and the pressure is 20 mTorr. In the etching process using this gas, nitrogen (N) firstly reacts with carbon (C) to produce CN. N then reacts with H to produce HCN having high volatility, and the HCN is discharged. This means that the carbon can be etched by N and H with high controllability. Additionally, the side walls of the cylinder holes 26 are protected by (CN)ₓ which is formed thereon as an alteration layer. As a result, the side etching of the side walls can be prevented.

Since the etching gas contains a great amount of Ar which is an inert gas, anisotropic etching can be obtained by utilizing the straightness of the ion orbit. If no discharge path is ensured for the electric charge, the film of amorphous carbon 23 to be etched will be charged up with the positive charge from the Ar ions, whereby the ion orbit will be deformed, making it impossible to achieve perfect anisotropy. It is believed that the charge-up occurs principally in the vicinity of the mouths of the cylinder holes 26.

According to the manufacturing method of this embodiment, in contrast, a discharge path for discharging the electric charge is provided by using the amorphous carbon 23 having electrical conductivity as the film to be etched and additionally providing the discharge plugs 22. This makes it possible to prevent the charge-up and to keep the anisotropy of the etching even when the dry etching for forming the cylinder holes 26 progresses. Consequently, the bowing can be prevented effectively.

Since O₂ gas contained in the etching gas is apt to etch carbon isotropically, the flow rate of O₂ is set as low as possible in comparison with NH₃ or Ar. In the etching gas used in this embodiment, the flow rate of Ar is increased to dilute O₂. As a result, substantially no adverse effect of O₂ is observed on the shape forming. It should be noted that the O₂ is contained in order to increase the etching rate, whereby the etching rate is improved up to about 1.5 times higher as compared to the case of no O₂ contained.

A description will be made of a comparative example in which SiO₂ is used as a film to be etched. When the SiO₂ is etched with fluorocarbon (CxFy) gas, deposition occurs during formation of holes and a deposition film is formed on the side walls of the holes. This means that the etching shape will inevitably be a forward tapered shape to some degree or another. As a result, the bottom surface area of the capacitor is made smaller, the capacity is made smaller, or the contact resistance with conductor plugs arranged below is increased.

In contrast, in the process shown in FIG. 4B, the side wall is protected with an alteration layer which is produced by N reacting with C in the side wall, whereby the side wall can be prevented from the side etching. Further, a discharge path composed of the amorphous carbon 23 and the discharge plugs 22 are provided, whereby the charge-up is avoided and the bowing can be prevented effectively. As a result, the control is made relatively easy to ensure the etching anisotropy and to form the side wall with a vertical profile. Therefore, the cylinder holes 26 can be formed to have side walls with a vertical profile even if the cylinder holes 26 are formed with a high aspect ratio.

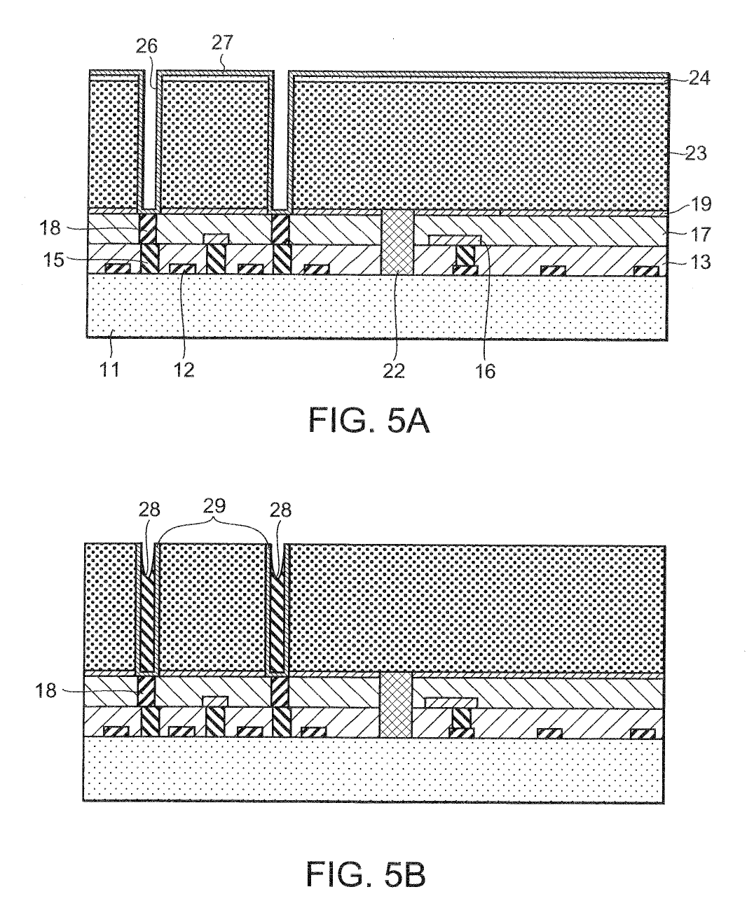

Next, in the process shown in FIG. 5A, TiN as a lower electrode material 27 is deposited by CVD to form a film with a thickness of 20 nm on top of the cylinder holes 26 and the hard mask 24. FIG. 5A shows an enlarged view of the region enclosed by the bold lines in FIG. 4B.

Subsequently, in the process shown in FIG. 5B, the insides of the cylinder holes 26 are filled with a photoresist 28, and the lower electrode material (TiN) 27 is etched back by plasma etching to form lower electrodes 29 on the inner wall surfaces of the cylinder holes 26. The lower electrodes 29 are in contact with the second conductor plugs 18 at the bottoms thereof. A commercially available ICP-type plasma etcher is used for the plasma etching. The etching gas conditions are set such that BCl₃/Cl₂=50/50 (sccm) and the pressure is 15 mTorr.

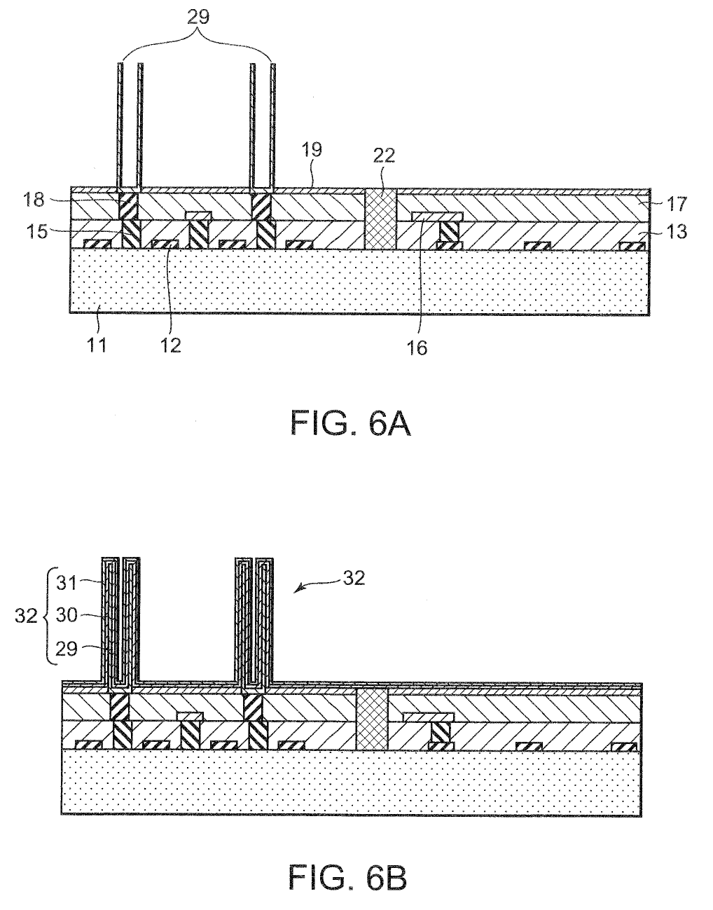

Next, in the process shown in FIG. 6A, an oxygen-containing gas is used to perform ashing (O₂ plasma processing) at a high temperature stage of about 2000°, whereby the photoresist 28 in the cylinder holes 26 is removed and, at the same time, all the exposed amorphous carbon 23 is removed. This process is a so-called “trimming” process. Although most of the photoresist 28 and the amorphous carbon 23 can be removed only by the ashing, any residue can be removed substantially perfectly by spraying a mist of an acid peeling solution and heat treated at 200° C.

In the trimming process, the exposed amorphous carbon 23 is removed by the plasma etching using no chemical solution, and thus the unnecessary etching of the part supporting the lower electrodes 29 can be prevented, and the lower electrodes 29 can be prevented from collapsing due to surface tension occurring during drying.

Subsequently, in the process shown in FIG. 6B, a stacked layer of HfO₂ (hafnium oxide) and Al₂O₃ (alumina) is formed by CVD on the surfaces of the lower electrodes 29 to a thickness of 10 nm as a capacitive insulating film (high dielectric film) 30. Further, an upper electrode 31 of TiN is formed by CVD to a thickness of 10 nm so as to oppose each of the lower electrodes 29 with the high dielectric film 30 interposed therebetween. In this manner, crown-shaped capacitors 32 are formed, each consisting of the lower electrode 29, the high dielectric film 30, and the upper electrode 31.

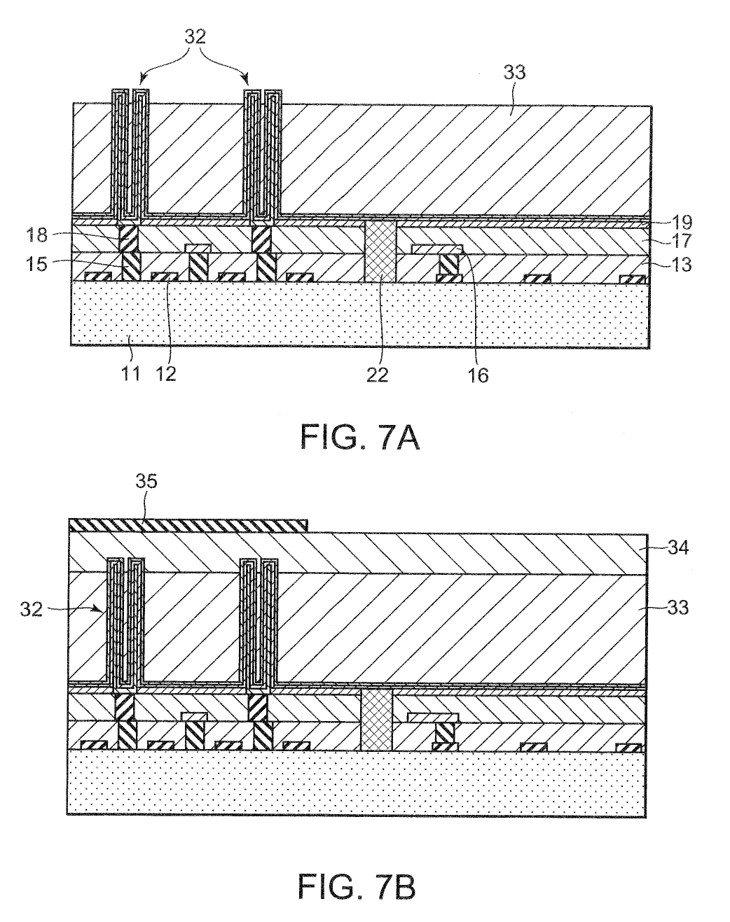

Next, in the process shown in FIG. 7A, commercially available SOD (Spin On Dielectrics) is used as an interlayer insulating film (backfill interlayer film) 33 to bury the capacitors again, and then is etched back to such an extent that about several tens of nanometers of the tops of the capacitors 32 are exposed.

Subsequently, in the process shown in FIG. 7B, a film 34 of W is formed by sputtering on the exposed top parts of the capacitors 32 and the top of the backfill interlayer insulating film 33. Further, at least a region of the film 34 covering the capacitors 32 is covered with a photoresist 35.

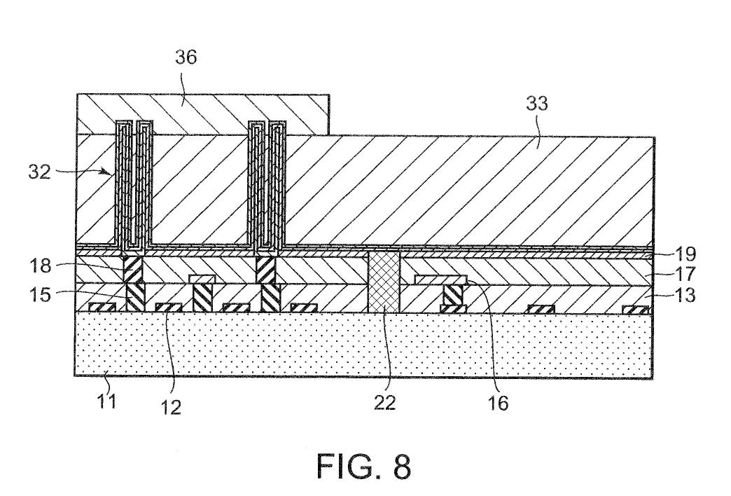

Next, in the process shown in FIG. 8, the film 34 made of W is plasma etched to form a plate electrode 36. The plasma etching is performed by using a commercially available ICP plasma etcher. The gas conditions are set such that SF₆/Cl₂/O₂=50/15/10 (sccm), and the pressure is 10 mTorr.

After that, the plate electrode 36 and the backfill interlayer film 33 are covered with an interlayer insulating film 37 consisting of SiO₂ formed by plasma CVD, as shown in FIG. 1. Subsequently, a shallow contact (third conductor plug) 38 to be connected to the plate electrode 36 and a deep contact (first through-hole) 39 to be connected to the second wiring line (bit line) 16 are formed simultaneously. Further, third wiring lines (Al wiring lines) 40 are formed to be connected to the contacts 38 and 39. The semiconductor device 10 as shown in FIG. 1 is thus manufactured by the processes as described above. From the next step onward, conventional processes are used to complete a DRAM device.

Using the manufacturing method as described above, dry etching was performed with the use of a mask having a 50 nm diameter hole. As a result, a cylinder hole could be obtained with a bowing amount of 5 nm or less and an aspect ratio of 30 or more. Thus, according to the manufacturing method of the exemplary embodiment of the present invention, cylinder holes with a high aspect ratio can be formed while preventing the bowing effectively.

Although in the embodiment described above, the region substantially corresponding to the region of the amorphous carbon 23 removed by the trimming process is filled back with SOD serving as the interlayer insulating film 33 by the process shown in FIG. 7A, the present invention is not limited to this. The removed region may be used as an air gap without being filled back with the interlayer insulating film 33.

The manufacturing method of a semiconductor device according to the present invention includes, as an aspect thereof, the steps of: forming a diffusion layer in a region of the surface of a semiconductor substrate and forming a first insulating film on top thereof; forming a discharge plug and a conductor plug passing through the first insulating film to be in contact with a region of the surface of the semiconductor substrate not including the diffusion layer and with a region of the surface of the diffusion layer, respectively; forming a carbon-containing film having electrical conductivity to cover the first insulating film, the discharge plug, and the conductor plug; forming a first conductive film passing through the carbon-containing film to be in contact with the conductor plug; and removing the carbon-containing film to expose the first conductive film.

According to the manufacturing method thus configured the first conductive film will not collapse during the removal of the carbon-containing film. Further, since the first conductive film is formed to pass through the electrically conductive carbon-containing film, the electric charge to charge the carbon-containing film is discharged through the discharge path composed of the carbon-containing film and the discharge plug which is in contact with the semiconductor substrate. As a result, the charge-up can be prevented and thus the bowing can be prevented.

Further, the following aspects can be employed in the manufacturing method of a semiconductor device according to the present invention.

The manufacturing method of a semiconductor device according to the present invention may further include, following the step of exposing the first conductive film, a step of depositing a second insulating film to bury the exposed first conductive film. In this manner, an insulating film is thus deposited as an interlayer film after the removal of the electrically conductive carbon-containing film used for providing an electrical discharge path, whereby it is made easy to form another layer on the insulating film.

The process for forming the first conductive film includes a step of forming a through-hole in the carbon-containing film by dry etching, and a step of depositing the first conductive film in the through-hole. According to this method, the electric charge can be discharged through the discharge path composed of the carbon-containing film and the discharge plugs during the dry etching, and thus the through-hole can be formed while preventing the charge-up.

The first conductive film is deposited on the surface of the inner wall of the through-hole passing through the carbon-containing film. The manufacturing method of the invention further includes a step of forming a capacitive insulating film on the surface of the inner wall of the first conductive film and a step of depositing a second conductive film so as to oppose the first conductive film with the capacitive insulating film interposed therebetween, between the step of forming the first conductive film and the step of forming the second insulating film. This makes it possible to form a capacitor composed of the first conductive film serving as the lower electrode, the second conductive film serving as the upper electrode, and the capacitive insulating film formed between these electrodes.

In the process for forming the through-hole, a gas consisting of NH₃, Ar, and O₂ is used, while the proportion of O₂ is smaller than those of NH₃ and Ar. In this case, the N forms an alteration layer on the side wall of the through-hole to prevent the side etching of the side wall, while the Ar maintains the anisotropy of etching. Further, the O₂ improves the etching rate. As a result, the side wall of the through-hole can be etched to have a vertical profile.

The process for removing the carbon-containing film includes ashing with an O₂-containing gas. The exposed carbon-containing film is thus removed by ashing, whereby the need of an etching process using a chemical solution is eliminated. Accordingly, the unnecessary etching of the part supporting the first conductive film and the occurrence of surface tension during drying can be prevented. As a result, the collapse of the first conductive film can be prevented.

The process for forming the discharge plug and the conductor plug includes a step of forming a conductor plug, a step of covering the surface of the conductor plug with a protecting film, and a step of forming a discharge plug, sequentially in this order. Accordingly, during the formation of the discharge plug, the conductor plug can be protected and the carbon-containing film can be formed to be in contact with the discharge plug.

The carbon-containing film is an amorphous film. For example, the carbon-containing film may be a film principally composed of carbon, such as a film of amorphous carbon. This makes it possible to form the through-hole by dry etching, and to expose the first conductive film by ashing. The first conductive film is a metal film. For example, the first conductive film may be formed of TiN.

According to the exemplary embodiment of the present invention, the carbon-containing film can be removed while preventing the collapse of the first conductive film, and the charge-up in the carbon-containing film can be prevented to prevent the bowing.

Although the present invention has been described in conjunction with a few preferred embodiments thereof, the invention is not limited to the foregoing embodiments but may be modified in various other manners without departing from the scope of the appended claims.

What is claimed is:

1. A method of manufacturing a semiconductor device, comprising:
forming a diffusion layer in a semiconductor substrate;
forming a first insulating film so as to cover the diffusion layer on the semiconductor substrate;
forming a discharge plug and a conductor plug so as to pass through the first insulating film the discharge plug being in contact with a surface region of the semiconductor substrate except for the diffusion layer while the conductor plug being in contact with a surface region of the diffusion layer;
forming a carbon-containing film having electrical conductivity so as to cover the first insulating film, the discharge plug and the conductor plug;
forming a first conductive film so as to pass through the carbon-containing film and to be in contact with the conductor plug; and
exposing the first conductive film by removing the carbon-containing film.

2. The method as claimed in claim 1, further comprising:
depositing a second insulating film so as to cover the first conductive film after exposing the first conductive film.

3. The method as claimed in claim 1, wherein the forming of the first conductive film comprises;
forming a through-hole in the carbon-containing film by dry etching, and
depositing the first conductive film in the through-hole.

4. The method as claimed in claim 3, wherein the first conductive film is deposited on an inner wall of the through-hole and
the method further comprises between the forming of the first conductive film and the forming of the second insulating film;
forming a capacitive insulating film on an inner wall of the first conductive film, and
depositing a second conductive film so as to oppose the first conductive film with the capacitive insulating film interposed therebetween.

5. The method as claimed in claim 3, wherein a gas comprising NH₃, Ar, and O₂ is used the forming of the through-hole, and
a proportion of the O₂ in the gas is lower than proportions of the NH₃ and the Ar.

6. The method as claimed in claim 1, wherein the removing of the carbon-containing film comprises ashing by using an O₂-containing gas.

7. The method as claimed in claim 1, wherein the forming the discharge plug and the conductor plug sequentially comprises;
forming the conductor plug,
covering a surface of the conductor plug with a protecting film, and
forming the discharge plug.

8. The method as claimed in claim 1, wherein the carbon-containing film comprises an amorphous film.

9. The method as claimed in claim 1, wherein the first conductive film comprises a metal film.
